(19) United States
(12) Patent Application Publication
(10) Pub. No.: US 2019/0137778 A1
(43) Pub. Date: May 9, 2019

(54) SPECKLE LASER DEVICE BASED ON LOW TIME COHERENCE AND LOW SPATIAL COHERENCE, AND PREPARATION METHOD THEREFOR

(71) Applicant: PAVILION INTEGRATION CORPORATION (SUZHOU), Suzhou, Jiangsu Province (CN)

(72) Inventors: Ningyi LUO, Suzhou (CN); Hui FAN, Suzhou (CN)

(73) Assignee: PAVILION INTEGRATION CORPORATION (SUZHOU), Suzhou, Jiangsu Province (CN)

(21) Appl. No.: 16/093,632

(22) PCT Filed: Apr. 13, 2017
(86) PCT No.: PCT/CN2017/080388

§ 371 Date: Dec. 14, 2018

(30) Foreign Application Priority Data
Apr. 14, 2016 (CN) 201610230499.4

(51) Int. Cl. G02B 27/48; H01S 5/00; G02B 27/42

(52) U.S. Cl. CPC G02B 27/48; G02B 27/4205; H01S 5/0085

(57) ABSTRACT

A speckle laser device based on low time coherence and low spatial coherence, and a preparation method therefor. The speckle laser device comprises a radio frequency modulator (1), a laser device (2), a diffracting optical element (3) and a focusing lens (4) that are coaxially and sequentially disposed on a same optical platform. The diffracting optical element (3) is located in the emergent direction of the laser device (2), the radio frequency modulator (1) modulates the laser device (2), and laser (001) modulated by the radio frequency modulator (1) enters the diffracting optical element (3). Laser beams emerging from the diffracting optical element (3) are zero-coherent speckle laser beams (002), the laser beams (002) enter the focusing lens (4), and the laser emerging from the focusing lens (4) forms a focused speckle laser (003). Speckle laser output beams are obtained by using a time coherence and spatial coherence reduction technology, and the problem of speckle production due to time coherence and spatial coherence is resolved.

### FIELD OF THE PRESENT DISCLOSURE

The present invention relates to the technical field of lasers, and in particular to a speckle-free laser based on low time coherence and low spatial coherence and a manufacturing method therefor.

### BACKGROUND OF THE PRESENT DISCLOSURE

Laser has the characteristics of high brightness, high coherence, high collimation, and the like, and therefore is widely applied in aspects such as industry, communication, medical treatments, laser detection and measurement, and instruments. The laser has a light beam that is highly coherent and has different amplitudes and phases, and irregularly distributed granular speckles-laser speckles are formed at each point in a space. The laser speckle, serving as a random process, is an objective physical phenomenon that necessarily exists due to use of a laser. The laser speckle not only causes energy loss, but also becomes a main factor that limits image quality and reduces an image resolution and a contrast. For example, currently, in the fields of laser projection display and laser illumination that are researched and applied, the laser speckle has become a key for limiting laser display to achieve actual practicability.

At present, there are various methods for eliminating laser speckles, and the methods generally can be divided into two types. One is a static speckle eliminating method, such as reducing a laser cavity length, or performing beam combining after beam splitting is carried out on incident light beams in an optical path, to reduce coherence of the incident light beams. This method is complex in operation and low in connection stability of the optical path. According to the “UNIFORM-LIGHT SHAPING AND SPECKLE ELIMINATING DEVICE FOR LASER BEAM” disclosed in CN102122081A, a pure phase diffraction device is driven by an electromagnetic vibration device to complete uniform-light shaping and speckle eliminating functions. According to the “METHOD FOR ELIMINATING LASER SPECKLE EFFECT” disclosed in CN101950087A, for an incident light beam, a light beam phase is damaged through a vibrating transparent liquid, so as to eliminate a laser speckle effect.

The other is a dynamic speckle eliminating method, in which dynamic processing is carried out on laser speckles, and the speckles are inhibited by means of time average, such as a rotary or vibrating scattering body (frosted glass, a liquid crystal device, a phase plate) and an ultrasonic method. When the dynamic speckle method is used, a faster speckle change frequency indicates a smaller correlation between the speckles, and indicates a better speckle inhibition effect after the time average. However, at present, the dynamic speckle method adopted is complex in structure and is poor in system stability. In current speckle elimination, a speckle frequency control range is limited, and a phase adjustment depth is small, so that the speckle correlation is relatively great. The speckle inhibition effect is reduced due to the foregoing factors, and meanwhile, the incident light beam is relatively low in energy utilization rate and large in energy loss after passing through the liquid crystal device and the frosted glass, and the performance of the system is affected due to an angle expansion phenomenon.

In view of the above, both the static speckle eliminating method and the dynamic speckle eliminating method reduce impacts of laser speckles on the performance of the system in view of a laser (or laser). In the process, the two methods merely reduce the impacts of the laser speckles on the performance of the system, but cannot evaluate the system in real time and reduce or compensate the system, thereby obtaining image data having low speckle impact and a high signal-to-noise ratio.

### SUMMARY OF THE PRESENT DISCLOSURE

An objective of the present invention is to resolve the foregoing problem existing in the prior art. The present invention provides a speckle-free laser based on low time coherence and low spatial coherence and a manufacturing method therefor, so that a light beam with a speckle-free laser output is obtained through a technology for reducing time coherence and the low space coherence.

The objective of the present invention is achieved by the following technical solution: a speckle-free laser based on low time coherence and low spatial coherence, including a radio frequency modulator for reducing time coherence of laser beams, a laser, a diffractive optical element for reducing spatial coherence of the laser beams, and a focusing lens that are coaxially and sequentially disposed on a same optical platform, where the diffractive optical element is located in an emission direction of the laser; the radio frequency modulator modulates the laser; laser modulated by the radio frequency modulator is incident into the diffractive optical element; the laser beam emitted by the diffractive optical element is a coherence-free speckle laser beam based on low time coherence and low spatial coherence; the laser beam is incident into the focusing lens; and the laser emitted by the focusing lens forms focused speckle-free laser.

Preferably, under a modulation function of the radio frequency modulator, a time-coherence length of the laser emitted by the laser becomes short, and forms laser having a low time-coherence property.

Preferably, the laser having a low time-coherence property passes through the diffractive optical element (3); and a wavefront of the laser is reconstructed, where a phase part of a single part of the reconstructed laser wavefront generates an offset.

Preferably, the phase offset is matched with a coherence length of the laser having a low time-coherence property, and an obtained matching relationship is a position relatonship that a low time-coherence condition can be formed exactly relative to an adjacent laser part having a low time-coherence property or the laser having a low time-coherence property, so that a laser output with the coherence-free speckle based on the low time coherence and the low spatial coherence is achieved.

Preferably, the laser emission with the coherence-free speckle based on the low time coherence and the low spatial coherence passes through a focusing lens part, an emission wavefront of the laser is reconstructed again, and the laser emission with the coherence-free speckle based on the low time coherence and the low spatial coherence is focused under an reconstruction effect of the emission wavefront, to obtain focused laser with coherence-free speckle based on low time coherence and low spatial coherence.

Preferably, a material of the diffractive optical element can be fused silica, optical glass, or an optical resin material; and the diffractive optical element is manufactured by a mould pressing process or an etching process.

The present invention further provides a method for manufacturing a speckle-free laser based on low time coherence and low spatial coherence, including the following steps:

S1: selecting a radio frequency modulator, a laser, a diffractive optical element, and a focusing lens and coaxially and sequentially disposing the same on an optical platform;

S2: turning on the radio frequency modulator and the laser, where the radio frequency modulator modulates the laser, and a time-coherence length of laser emitted after being modulated by the radio frequency modulator becomes short, and forms laser having a low time-coherence property;

S3: after the laser having a low time-coherence property generated in step S2 passes through the diffractive optical element, reconstructing a wavefront of the laser, where a phase part of a single part of the reconstructed wavefront generates an offset;

S4: after step S3, matching a coherence length of the laser having a low coherence property with the phase offset, where an obtained matching relationship is a position relationship that a low time-coherence condition can be formed exactly relative to an adjacent laser part having a low time-coherence property or the laser having a low time-coherence property, so that a laser output with the coherence-free speckle based on the low time coherence and the low spatial coherence is achieved;

S5: after step S4, enabling the laser emission with the coherence-free speckle based on the low time coherence and the low spatial coherence to pass through a focusing lens part, reconstructing an emission wavefront of the laser again, and focusing the laser emission with the coherence-free speckle based on the low time coherence and the low spatial coherence under an reconstruction effect of the emission wavefront, to finally form focused laser with the coherence-free speckle based on low time coherence and low spatial coherence.

The technical solution of the present invention mainly has the advantage that the present invention provides a speckle-free laser based on low time coherence and low spatial coherence and a manufacturing method therefor, and a light beam with a speckle-free laser output is obtained through a technology for reducing time coherence and spatial coherence. Compared with existing technical solutions, a problem of speckles caused by time coherence and spatial coherence is resolved, so that a laser with a speckle-free laser output is obtained.

### BRIEF DESCRIPTION OF THE DRAWINGS

FIG. 1 is a schematic structural diagram of a speckle-free laser according to the present invention; and

FIG. 2 is a comparison schematic diagram when laser speckles exist and speckles do not exist.

### DESCRIPTION OF THE EMBODIMENTS

The objectives, advantages, and features of the present invention will be illustrated and explained by way of non-limiting description of the following preferred embodiments, and these embodiments are only typical examples that apply the technical solutions of the present invention. All technical solutions formed by adopting equivalent replacement or equivalent transformation fall within the protection scope of the present invention.

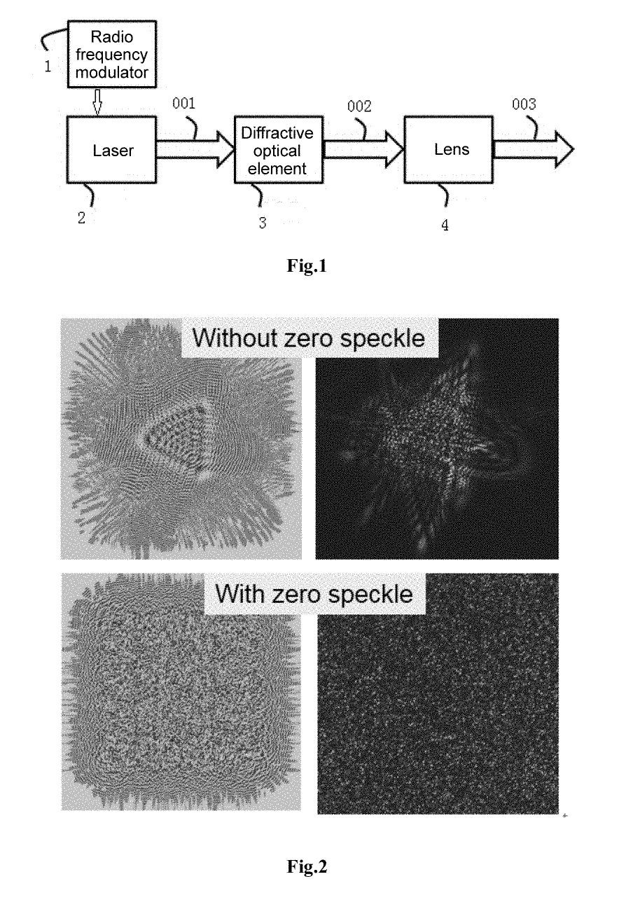

As shown in FIG. 1, a speckle-free laser based on low time coherence and low spatial coherence is provided, including a radio frequency modulator 1 for reducing time coherence of laser beams, a laser 2, a diffractive optical element 3 for reducing spatial coherence of the laser beams, and a focusing lens 4 that are coaxially and sequentially disposed on a same optical platform.

In this embodiment, the laser 2 is preferably a semiconductor laser. Selecting the semiconductor laser has the advantages that: the semiconductor laser has a wide wavelength range, is simple to be manufactured, is low in costs, has high laser utilization efficiency, is easy for mass production, has a small volume, has a light weight, has long service life, has a high cost performance, and saves power.

The diffractive optical element 3 is located in an emission direction of the laser 2, and a material of the diffractive optical element 3 may be fused silica, optical glass, or an optical resin material. In this embodiment, the material of the diffractive optical element 3 is preferably an optical resin material. The optical resin material is selected due to that the optical resin has the following advantages. The optical resin is good in transparency and light transmission: in a visible light area, a light transmittance of the optical resin is similar to that of glass; in an infrared light area, the light transmittance of the optical resin is slightly higher than that of the glass; and in an ultraviolet area, the light transmittance is reduced as a wavelength is reduced from 0.4 micron, and light with wavelengths smaller than 0.3 micron is almost completely absorbed. In addition, the optical resin has a strong impact resistance capability: the impact resistance capability of the optical resin is several times of that of the glass, and therefore, the optical resin is not easy to be broken, and is safe and durable. Certainly, in a working process, optical glass can also be selected. When the optical glass is selected, the optical glass is preferably the BK7 glass manufactured by the SCHOTT company from German. The BK7 glass is equivalent to the K9 glass in China, and specific parameters of the BK7 glass are as follows: a refractive index is 1.51680, an acid resistance is 1, and K's hardness is 610.

The diffractive optical element 3 is manufactured by a mould pressing process or an etching process, and the diffractive optical element 3 is suitable for various lasers such as Nd:YNG, CO2, a femtosecond laser, a semiconductor laser, and the like to perform beam shaping. Main applications of the diffractive optical element 3 include laser beam shaping (such as laser processing, medical treatment, an imaging system, a sensor, round or square flat-top beam shaping, a matrix, a grid, a line shape, and circular pattern shaping) and a phase device used in astronomy.

When the radio frequency modulator 1 and the laser 2 work, the radio frequency modulator 1 modulates the laser 2. Under a modulation function of the radio frequency modulator 1, a time-coherence length of the laser emitted by the laser 2 becomes short, that is, the laser coherence time becomes short, and laser 001 having a low time-coherence property is formed.

The laser 001 modulated by the radio frequency modulator 1 is incident into the diffractive optical element 3. The laser beam emitted through the diffractive optical element 3 is a coherence-free speckle laser beam 002 based on low time coherence and low spatial coherence. The laser having a low time-coherence property passes through the diffractive optical element 3. A wavefront of the laser is reconstructed, and a phase part of a single part of the reconstructed laser wavefront generates an offset.

A function of the diffractive optical element 3 is to reconstruct the wavefront of the laser. A phase part of a single part of the further constructed wavefront of the laser generates an offset, and the phase offset is matched with a coherence length of the laser having a low time-coherence property. An obtained matching relationship is a position relationship that a low time-coherence condition can be formed exactly relative to an adjacent laser part having a low time-coherence property or the laser having a low time-coherence property.

Laser beams with spatial coherence that are reduced by the diffractive optical element 3 are incident into the focusing lens 4, and the laser emitted by the focusing lens 4 forms focused speckle-free laser 003. The phase offset is matched with the coherence length of the laser having a low time-coherence property, and the obtained matching relationship is a position relationship that a low time-coherence condition can be formed exactly relative to an adjacent laser part having a low time-coherence property or the laser having a low time-coherence property, so that a laser output with the coherence-free speckle based on the low time coherence and the low spatial coherence is achieved.

Laser emission with coherence-free speckle based on low time coherence and low spatial coherence passes through a focusing lens part, and an emission wavefront of the laser is reconstructed again. The laser emission of the coherence-free speckle based on the low time coherence and the low spatial coherence is focused under an reconstruction effect of the emission wavefront, to finally form focused laser with the coherence-free speckle based on the low time coherence and the low spatial coherence. FIG. 2 is a comparison schematic diagram of a speckle-free laser with laser speckles and the speckle-free laser without speckles. It can be seen from FIG. 2 that: for a laser before laser speckles are eliminated, the laser speckles are irregularly distributed granular speckles; time coherence of the laser modulated by RF is reduced; a laser beam modulated by the RF is incident into the diffractive optical element and then the spatial coherence is reduced; and the laser of which the spatial coherence is reduced by the diffractive optical element is incident into the focusing lens, to obtain a focused laser beam with coherence-free speckle based on low time coherence and low spatial coherence. The foregoing are specific presentations of low spatial coherence and low time coherence, and a speckle-free or low speckle output can be obtained.

Some coherent waves in each wavefront are spatially coherent in an axial direction. C composite coherence degree g (r1,r2) depends on time delay. Time coherence and spatial coherence of light have position characteristics. A time-coherence characteristic is described by g (r1, r2, 0), and separate axial distances of a fluctuation at two points being greater than a coherence length approximately is not related. A light propagation wave and a complex wave function need to meet a wave equation, and time and spatial fluctuations of the light are closely related. A composite coherence degree g (r1, r2, 0) of quasi-monochromatic light waves is represented by g (r1, r2). DOE (the diffractive optical element) can enable a resolution of a coherent area to be smaller than a resolution of an optical system. The composite coherence degree of the coherence g (r1, r2) can be considered as infinitesimal, that is, all r1 is not equal to r2.

In an extreme case, light with g (r1, r2)=0 is incoherent, and a spatial structure of a laser speckle pattern generated from a sufficient diffuse reflection surface is interfered by coherence of backscattering of light. A spatially coherent area except the wave is reversed at a low spatial-coherence illumination stage during conjugation time. No speckle or low speckle can be obtained by adding the DOE (the diffractive optical element) to the low coherence semiconductor laser.

The semiconductor laser is modulated at a high data rate, a laser spectrum is expanded due to transient spectrum phenomena, and different modulation indexes generate widened spectrums with different modulation depths. The semiconductor laser has a stable wide wave band without mode hopping, and can generate low time coherence. If ρ_{c} is defined as the coherence distance, ρ_{c} is equal to 1.22λ/θₛ s, where θₛ is equal to 2a/d and indicates an angle corresponding to a light source, a indicates a radius of a circle aperture, and d indicates a distance from the light source to an observed wavefront. For example, if a wavelength λ of the light source is equal to 0.5 μm, and θₛ is equal to 0.5°, a coherence distance ρ_{c} from the light sources to the observed wavefront is equal to 115λ=57.5 μm.

In addition, the present invention further provides a method for manufacturing a speckle-free laser based on the low time coherence and low spatial coherence, including the following steps:

S1: selecting a radio frequency modulator, a laser, a diffractive optical element, and a focusing lens and coaxially and sequentially disposing the same on an optical platform;

S2: turning on the radio frequency modulator and the laser, where the radio frequency modulator modulates the laser, and a time-coherence length of laser emitted after being modulated by the radio frequency modulator becomes short, and forms laser having a low time-coherence property;

S3: after the laser having a low time-coherence property generated in step S2 passes through the diffractive optical element, reconstructing a wavefront of the laser, where a phase part of a single part of the reconstructed wavefront generates an offset;

S4: after step S3, matching a coherence length of the laser having a low coherence property with the phase offset, where an obtained matching relationship is a position relationship that a low time-coherence condition can be formed exactly relative to an adjacent laser part having a low time-coherence property or the laser having a low time-coherence property, so that a laser output with the coherence-free speckle based on the low time coherence and the low spatial coherence is achieved;

S5: after step S4, enabling the laser emission with the coherence-free speckle based on the low time coherence and the low spatial coherence to pass through a focusing lens part, reconstructing an emission wavefront of the laser again, and focusing the laser emission with the coherence-free speckle based on the low time coherence and the low spatial coherence under an reconstruction effect of the emission wavefront, to finally form focused laser with the coherence-free speckle based on low time coherence and low spatial coherence.

Through the above description, it can be found that the present invention discloses a speckle-free laser and a manufacturing method therefor. The core is to reduce time coherence and spatial coherence at the same time, to obtain a light beam output by speckle-free laser. Compared with the prior art, the present invention resolves a problem of speckles caused by time coherence and spatial coherence, so that a laser with a speckle-free laser output is obtained. The laser provided in the present invention is compact in structure, can obtain coherence-free speckle laser, significantly improves a light energy utilization rate during a practical application process, and the has the advantages of being small in size, low in costs, produced in batches, and the like.

Certainly, the above descriptions are merely embodiments of the present invention, and are not intended to limit the patent scope of the present invention. Any equivalent structure or equivalent process conversion made by using the specification and the accompanying drawings of the present invention, directly or indirectly applied to other related technical fields, all fall within the patent protection scope of the present invention.

What is claimed is:

1. A speckle-free laser based on low time coherence and low spatial coherence, characterized by comprising a radio frequency modulator (1) for reducing time coherence of laser beams, a laser (2), a diffractive optical element (3) for reducing spatial coherence of the laser beams, and a focusing lens (4) that are coaxially and sequentially disposed on a same optical platform, wherein, the diffractive optical element (3) is located in an emission direction of the laser (2); the radio frequency modulator (1) modulates the laser (2); laser modulated by the radio frequency modulator (1) is incident into the diffractive optical element (3); the laser beam emitted by the diffractive optical element (3) is a coherence-free speckle laser beam based on low time coherence and low spatial coherence; the laser beam is incident into the focusing lens (4), and the laser emitted by the focusing lens (4) forms focused speckle-free laser.

2. The speckle-free laser based on low time coherence and low spatial coherence according to claim 1, characterized in that: under a modulation function of the radio frequency modulator (1), a time-coherence length of the laser emitted by the laser (2) becomes short, and forms laser having a low time-coherence property.

3. The speckle-free laser based on low time coherence and low spatial coherence according to claim 2, characterized in that: the laser having a low time-coherence property passes through the diffractive optical element (3); and a wavefront of the laser is reconstructed, wherein a phase part of a single part of the reconstructed laser wavefront generates an offset.

4. The speckle-free laser based on low time coherence and low spatial coherence according to claim 3, characterized in that: the phase offset is matched with a coherence length of the laser having a low time-coherence property, and an obtained matching relationship is a position relationship that a low time-coherence condition can be formed exactly relative to an adjacent laser part having a low time-coherence property or the laser having a low time-coherence property, so that a laser output with the coherence-free speckle based on the low time coherence and the low spatial coherence is achieved.

5. The speckle-free laser based on low time coherence and low spatial coherence according to claim 4, characterized in that: the laser emission with the coherence-free speckle based on the low time coherence and the low spatial coherence passes through a focusing lens part, an emission wavefront of the laser is reconstructed again, and the laser emission with the coherence-free speckle based on the low time coherence and the low spatial coherence is focused under an reconstruction effect of the emission wavefront, to obtain focused laser with coherence-free speckle based on low time coherence and low spatial coherence.

6. The speckle-free laser based on low time coherence and low spatial coherence according to claim 1, characterized in that: a material of the diffractive optical element (3) can be fused silica, optical glass, or an optical resin material.

7. The speckle-free laser based on low time coherence and low spatial coherence according to claim 1, characterized in that: the diffractive optical element (3) is manufactured by a mould pressing process or an etching process.

8. The speckle-free laser based on low time coherence and low spatial coherence according to claim 1, characterized in that: the laser (2) is a semiconductor laser.

9. A method for manufacturing a speckle-free laser based on low time coherence and low spatial coherence, characterized by comprising the following steps:
S1: selecting a radio frequency modulator, a laser, a diffractive optical element, and a focusing lens and coaxially and sequentially disposing the same on an optical platform;
S2: turning on the radio frequency modulator and the laser, wherein the radio frequency modulator modulates the laser, and a time-coherence length of laser emitted after being modulated by the radio frequency modulator becomes short, and forms laser having a low time-coherence property;
S3: after the laser having a low time-coherence property generated in step S2 passes through the diffractive optical element, reconstructing a wavefront of the laser, wherein a phase part of a single part of the reconstructed wavefront generates an offset;
S4: after step S3, matching a coherence length of the laser having a low time-coherence property with the phase offset, wherein an obtained matching relationship is a position relationship that a low time-coherence condition can be formed exactly relative to an adjacent laser part having a low time-coherence property or the laser having a low time-coherence property, so that a laser output with the coherence-free speckle based on the low time coherence and the low spatial coherence is achieved;
S5: after step S4, enabling the laser emission with the coherence-free speckle based on the low time coherence and the low spatial coherence to pass through a focusing lens part, reconstructing an emission wavefront of the laser again, and focusing the laser emission with the coherence-free speckle based on the low time coherence and the low spatial coherence under an reconstruction effect of the emission wavefront, to finally form focused laser with the coherence-free speckle based on low time coherence and low spatial coherence.
